(19) United States
(12) Patent Application Publication
(10) Pub. No.: US 2016/0056061 A1
(43) Pub. Date: Feb. 25, 2016

(54) REAL TIME LIQUID PARTICLE COUNTER (LPC) END POINT DETECTION SYSTEM

(71) Applicant: QUANTUM GLOBAL TECHNOLOGIES LLC, DUBLIN, PA (US)

(72) Inventors: Jiansheng Wang, Union City, CA (US); Barbara Stanczyk, Morgan Hill, CA (US); Wendell Boyd, JR., Morgan Hill, CA (US); Kevin A. Papke, Portland, OR (US); Joseph F. Sommers, San Jose, CA (US); David Do, Milpitas, CA (US)

(21) Appl. No.: 14/933,832

(22) Filed: Nov. 5, 2015

Related U.S. Application Data
(62) Division of application No. 13/034,386, filed on Feb. 24, 2011, now abandoned.

(51) Int. Cl. H01L 21/67; B08B 3/14; B08B 3/10; H01L 21/677

(52) U.S. Cl. CPC H01L 21/67051; H01L 21/67288; H01L 21/67724; B08B 3/14; B08B 3/102

(57) ABSTRACT

Embodiments of the present invention generally relate to a method and apparatus for ex-situ cleaning of a chamber component. More particularly, embodiments of the present invention generally relate to a method and apparatus for endpoint detection during ex-situ cleaning of a chamber component used in a semiconductor processing chamber. In one embodiment, a system for cleaning parts disposed in a liner with a cleaning fluid is provided. The system comprises a portable cart, a liquid particle counter (LPC) carried by the portable cart, the LPC configured for detachable coupling to a fluid outlet port formed through the liner, the LPC operable to sample rinsate solution exiting the line, and a pump carried by the portable cart and configured for fluid coupling to the liner in a detachable manner, the pump operable to recirculate rinsate solution through the liner.

### CROSS REFERENCE

This application is a division of U.S. application Ser. No. 13/034,386, filed Feb. 24, 2011, which application is incorporated herein by reference in its entirety.

### BACKGROUND OF THE INVENTION

1. Field of the Invention

Embodiments of the present invention generally relate to a method and apparatus for ex-situ cleaning of a chamber component. More particularly, embodiments of the present invention generally relate to a method and apparatus for endpoint detection during ex-situ cleaning of a chamber component used in a semiconductor processing chamber.

2. Description of the Related Art

In semiconductor substrate processing, the trend towards increasingly smaller feature sizes and line-widths has placed a premium on the ability to mask, etch, and deposit material on a semiconductor substrate with greater precision. As semiconductor features shrink, device structures become more fragile. Meanwhile, the killer defect size, defined as the particle size which renders the device non-functional, becomes smaller and more difficult to remove from the surface. Consequently, reducing device damage is one of the major issues facing the cleaning processes. As a result, this trend towards increasingly smaller feature sizes has placed a premium on the cleanliness of semiconductor manufacturing processes including the chamber component parts used in such processes.

Currently, cleaning processes which rely on particle counting to determine the end point of a cleaning process require off-line lab analysis during the component part cleaning process. This requires the operator to cease the cleaning process and manually pull a sample of the cleaning solution used in the cleaning process. This sample is then sent to a lab for analysis. This labor intensive process not only contributes to a significant increase in the length of the cleaning process but also increases tool downtime for the tool from which the part has been removed. This increase in tool downtime leads to a corresponding increase in the cost of ownership (CoO).

Therefore, there is a need for an improved apparatus and process for cleaning chamber component parts that provide improved removal of particle contaminants from chamber parts while significantly reducing downtime for chamber maintenance and cleaning.

### SUMMARY OF THE INVENTION

Embodiments of the present invention generally relate to a method and apparatus for ex-situ cleaning of a chamber component. More particularly, embodiments of the present invention generally relate to a method and apparatus for endpoint detection during ex-situ cleaning of a chamber component used in a semiconductor processing chamber. In one embodiment, a system for cleaning parts disposed in a liner with a cleaning fluid is provided. The system comprises a portable cart, a liquid particle counter (LPC) carried by the portable cart, the LPC configured for detachable coupling to a fluid outlet port formed through the liner, the LPC operable to sample rinsate solution exiting the line, and a pump carried by the portable cart and configured for fluid coupling to the liner in a detachable manner, the pump operable to recirculate rinsate solution through the liner.

In another embodiment, a system for cleaning parts disposed in a liner with a cleaning fluid is provided. The system comprises a portable cart, a liner for holding component parts to be cleaned during a cleaning process, and a liquid particle counter (LPC) carried by the portable cart, the LPC configured for detachable coupling to a fluid outlet port formed through the liner, the LPC operable to sample cleaning fluid exiting the liner.

In yet another embodiment, a method for cleaning parts disposed in a liner with a cleaning fluid is provided. The method comprises providing a liner for holding component parts to be cleaned during a cleaning process and a transducer positioned below the liner, providing a portable cart with a liquid particle counter (LPC) carried by the portable cart, the LPC configured for detachable coupling to a fluid outlet port formed through the liner, the LPC operable to sample cleaning fluid exiting the liner, positioning a component part in the liner, flowing a rinsate solution from a rinsate supply into the liner, cycling the transducer on and off to agitate the rinsate solution and remove contaminant particles from the component part, and monitoring a count of contaminant particles in the rinsate solution using the LPC, and ending the cleaning process when the count of contaminant particles drops below a previously determined level.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic side view of one embodiment of a cleaning system comprising a surface particle endpoint detection system according to embodiments described herein;

FIG. 2 is a fluid flow circuit schematic diagram of one embodiment of a surface particle endpoint detection system according to embodiments described herein;

FIG. 3 is a schematic side view of one embodiment of a cleaning system comprising a surface particle endpoint detection system according to embodiments described herein;

FIG. 4 is a schematic view of one embodiment of a wet bench set-up according to embodiments described herein; and

FIG. 5 is a schematic side view of one embodiment of a detachable cleaning cart comprising a surface particle endpoint detection system according to embodiments described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a method and apparatus for ex-situ cleaning of chamber component parts using a real-time surface particle endpoint detection system. Currently, cleaning processes use batch liquid particle counting (LPC) tests that require off-line lab analysis during the chamber component part cleaning process. This requires the system operator to manually pull a sample of the cleaning solution or rinsate solution and send the sample off-site for particle analysis. If the sample does not meet the required specifications for particle count, continued cleaning of the part is required along with the pulling of additional samples and corresponding tool downtime for particle count analysis. This results in high cost for repeated lab analysis followed by repeated cleaning sequences.

Certain embodiments described herein provide a stand-alone LPC system for detecting liquid particles extracted on-line from the chamber component parts during the cleaning process. This real-time LPC system measures particles during the cleaning cycle until reaching a desired endpoint/baseline (end point detection). The real-time LPC system may signal the operator when the chamber component part meets the desired endpoint/baseline. The real-time LPC system reduces or eliminates the need for the labor intensive LPC lab testing and the costs associated with such testing.

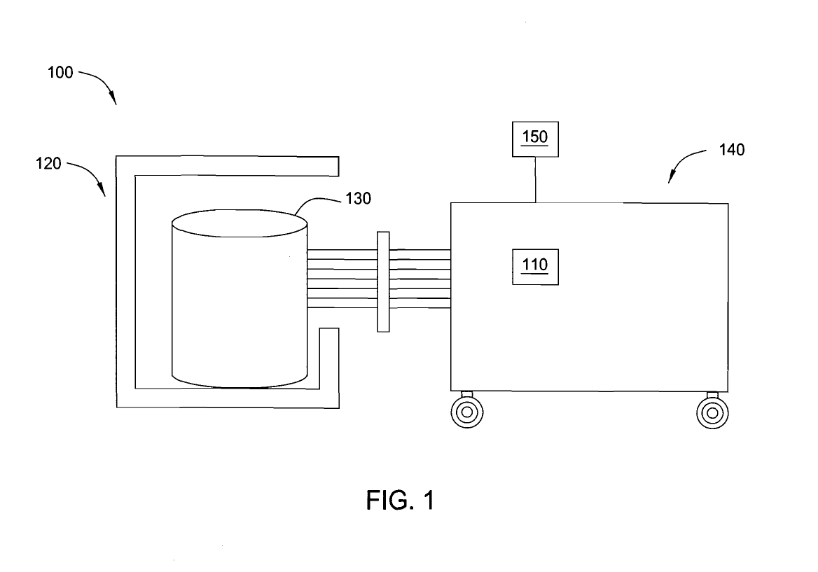

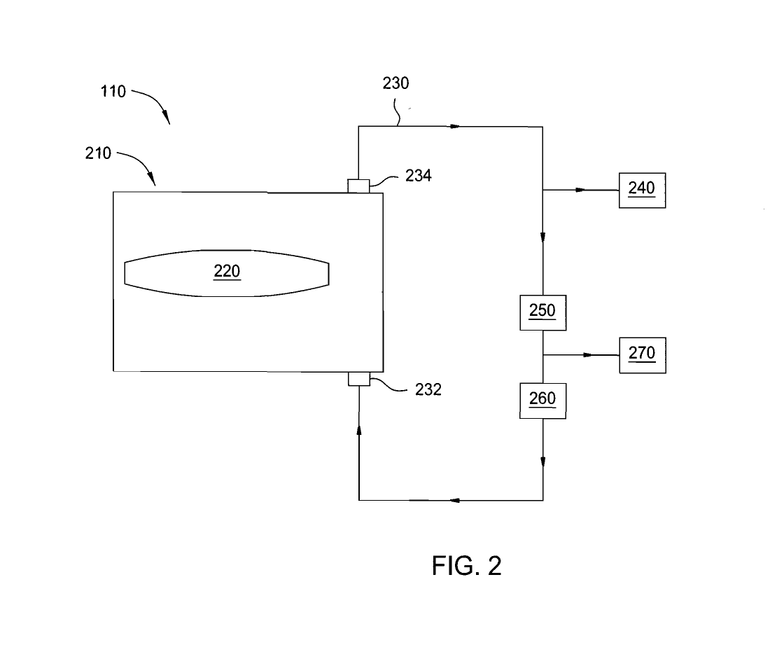

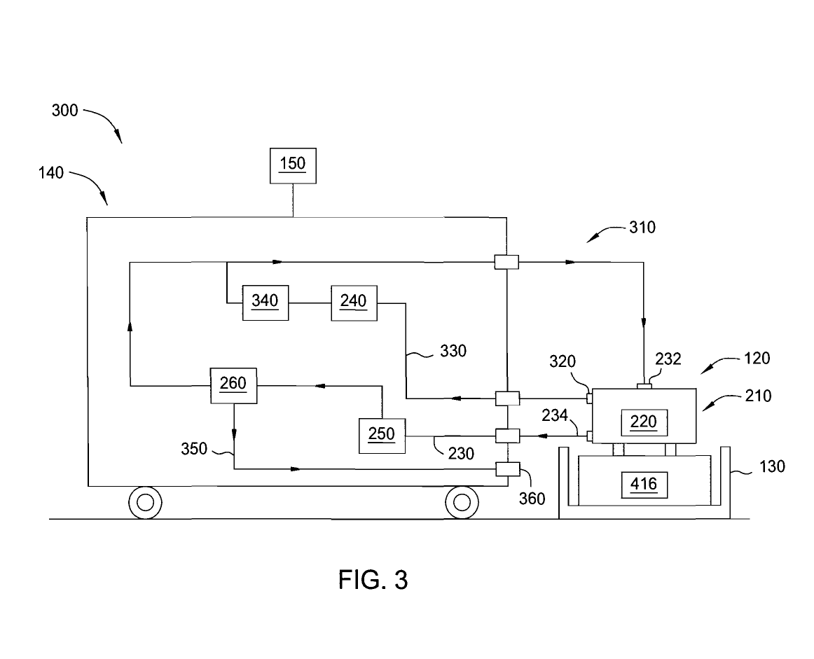

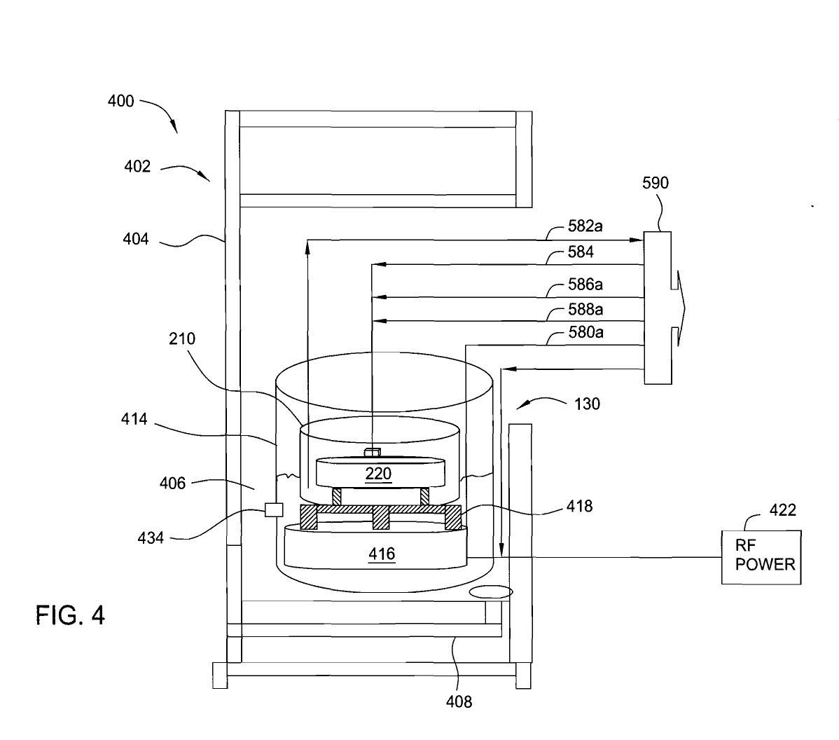

FIG. 1 is a schematic side view of one embodiment of a cleaning system 100 for ex-situ cleaning of chamber component parts comprising a surface particle endpoint detection system 110 according to embodiments described herein. In one embodiment, the one or more chamber component parts are used in a semiconductor processing chamber. The chamber component parts may include any chamber component part that requires cleaning. Exemplary chamber component parts include, but are not limited to, showerheads, pedestals, rings, bell jars, disks, and chamber liners. The chamber component parts may comprise materials including, but not limited to, silicon carbide, aluminum, copper, stainless steel, silicon, polysilicon, quartz and ceramic materials. In one embodiment, the cleaning system 100 comprises a wet bench set-up 120 which comprises a cleaning vessel assembly 130 for holding the chamber component parts to be cleaned during the cleaning process and a portable cleaning cart 140 which comprises the surface particle endpoint detection system 110 detachably coupled with the wet bench set-up for supplying the selected cleaning chemistry to the cleaning vessel assembly 130 during the cleaning process. The portable cleaning cart 140 is movable and may be detachably coupled with the cleaning vessel assembly 130 prior to and during the cleaning process and may be removed from the cleaning vessel assembly 130 when cleaning is not taking place. Thus, advantageously, the portable cleaning cart 140 may be used to service different cleaning vessels at different locations. The portable cleaning cart 140 may be configured to deliver one or more cleaning fluids toward the chamber component part 220. Cleaning fluids may include rinsate solution (e.g., deionized water (DIW)), one or more solvents, a cleaning solution such as standard clean 1 (SC1), selective deposition removal reagent (SDR), surfactants, acids, bases, or any other chemical useful for removing contaminants and/or particulates from a component part. The surface particle endpoint detection system 110, the wet-bench setup 120, and the portable cleaning cart 140 are described in further detail with reference to FIG. 2, FIG. 3, and FIG. 4.

In general, a system controller 150 may be used to control one or more controller components found in the cleaning system 100. The system controller 150 is generally designed to facilitate the control and automation of the overall cleaning system 100 and typically includes a central processing unit (CPU) (not shown), memory (not shown), and support circuits (or I/O) (not shown). The CPU may be one of any form of computer processors that are used in industrial settings for controlling various system functions, substrate movement, chamber processes, and support hardware (e.g., sensors, robots, motors, lamps, etc.), and monitor the processes (e.g., substrate support temperature, power supply variables, chamber process time, processing temperature, I/O signals, transducer power, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 150 determines which tasks are performable on a substrate. Preferably, the program is software readable by the system controller 150 that includes code to perform tasks relating to monitoring, execution and control of the movement, support, and/or positioning of a substrate along with the various process recipe tasks and various chamber process recipe steps being performed in the cleaning system 100. In one embodiment, the system controller 150 also contains a plurality of programmable logic controllers (PLC's) that are used to locally control one or more modules in the cleaning system 100.

FIG. 2 is a fluid flow circuit schematic diagram of the surface particle endpoint detection system 110 according to embodiments described herein. The surface particle endpoint detection system 110 comprises a liner 210 for holding a chamber component part 220 during the rinsing process, a circulating fluid supply line 230 for supplying rinsate to rinse the chamber component part 220, and one or more liquid particle counters (LPC) 240 fluidly coupled with the circulating fluid supply line 230 for monitoring the particle count in the circulating rinsate solution. A pump 250 may be positioned along the circulating fluid supply line 230 for pumping rinsate through the fluid supply line 230 and a filter 260 may be positioned along the rinsate fluid supply line 230 for removing particles from the rinsate solution.

The liner 210 may be positioned in the cleaning vessel assembly 130 of the wet bench setup 120 (See FIG. 3) during the cleaning process. The liner 210 may be positioned in the cleaning vessel assembly 130 during a portion of the cleaning process that involves the introduction of a rinsate solution, for example, deionized (DI) water into the cleaning vessel assembly. In certain embodiments where multiple cleaning and/or rinsate solutions are used during the cleaning process, a dedicated liner may be used for each separate solution. For example, in certain embodiments where the cleaning process comprises an etching step followed by a rinsing step, a dedicated etching liner may be used for the etching process and a dedicated rinsing liner may be used for the rinsing process. In certain embodiments where chamber component parts of different materials are cleaned, a dedicated liner may be used for each different material. In general, the liner may be made of plastic (e.g., polypropylene (PP), polyethylene (PE), polyvinyl difluoride (PVDF)) or coated metal (e.g., SST, aluminum with an ETFE coating) that will not be attacked by the cleaning chemistry and will not produce a significant amount of particulates which could contribute to an increased particle count by the LPC 240 thus creating a false or inaccurate endpoint reading.

The LPC 240 may be fluidly coupled with the liner 210 via the circulating fluid supply line 230. The circulating fluid supply line may be coupled with the liner 210 via a liner inlet 232 and a liner outlet 234. It should be understood that although a single liner inlet 232 and a single liner outlet 234 are shown; multiple liner inlets and liner outlets may be used depending upon the user's needs. The LPC 240 is used to detect and count particles in the rinsate fluid after the rinsate exits the liner 210 and the results are used to determine the endpoint of the cleaning process. In general, liquid particle counters use a high energy light source to illuminate particles as the particles pass through a detection chamber. As the particle passes through a beam generated by the light source (typically a laser) and if light scattering is used, the redirected light is detected by a photodetector. The endpoint may be determined by monitoring the light blocked by the particles of the rinsate fluid. The amplitude of the light scattered or light blocked is measured and the particle is counted and tabulated. The LPC 240 may be any LPC known to those of ordinary skill in the art. Exemplary LPC devices include, for example, the KL-28B Liquid-Borne Particle Counter available from RION Co., Ltd. of Japan and the LIQUILAZ® Particle Counter available from Particle Measuring Systems, Inc. of Boulder, Colo., USA. In certain embodiments, each LPC has its own pump.

Although shown in FIG. 2 as positioned prior to the pump 250 and filter 260, it should be understood that the LPC 240 may be positioned after the pump 250. However, it is believed to be preferable to position the LPC 240 prior to the pump 250 since turbulent flow created by the pump 250 may falsely increase the particle count readings by the LPC 240 leading to an inaccurate endpoint determination.

In certain embodiments, it may be desirable to use multiple liquid particle counters to achieve a more precise reading of the number of particles in the rinsate fluid. For example, in certain embodiments, a first liquid particle counter 240 may be positioned upstream relative to the pump 250 and a second liquid particle counter 270 may be positioned downstream from the pump 250 but upstream from the filter 260.

The filter 260 may be fluidly coupled with the circulating fluid supply line 230 downstream relative to the LPC 240. The filter 260 removes particles from the rinsate fluid allowing for the recirculation of fresh rinsate fluid into the liner 210. Exemplary filter sizes may include 0.01 micron to 10 micron filters. Exemplary filter sizes may also include 0.04 micron to 1 micron filters. Although a single filter 260 is shown in FIG. 2, it should be understood that the embodiments described herein contemplate the use of multiple filters of similar or varying sizes to filter particles from the rinsate solution.

FIG. 3 is a schematic side view of one embodiment of a cleaning system 300 comprising a surface particle endpoint detection system 310 according to embodiments described herein. The cleaning system 300 comprises the wet bench set-up 120 and the portable cleaning cart 140 comprising a surface particle endpoint detection system 310. The surface particle endpoint detection system 310 is similar to the surface particle endpoint detection system 110 depicted in FIG. 2 except that the liner 210 has a rinsate fluid sample outlet 320 fluidly coupled with a dedicated fluid sampling line 330 to which the LPC 240 is fluidly coupled. The dedicated fluid sampling line 330 may be fluidly coupled with the circulating fluid supply line 230. A dedicated sampling pump 340 for pumping rinsate through the dedicated fluid sampling line 330 may be positioned along the dedicated fluid sampling line 330.

The portable cleaning cart 140 may further comprise a drain line 350 that fluidly couples the filter 260 with a drain 360 for removing waste material from the filter 260.

In operation, with reference to FIG. 3, the chamber component part 220 is placed in the liner 210 for the cleaning process. In certain embodiments where the cleaning fluid includes a rinsate solution, the rinsate solution may be supplied from a rinsate solution source (not shown) to the circulating fluid supply line 230 where the rinsate solution flows into the liner 210 via liner inlet 232. In certain embodiments a transducer 416 may be used to agitate the rinsate solution flowing through the liner 210 and provide improved rinsing of the chamber component part 220. The contaminated rinsate solution exits the liner 210 via liner outlet 234 where the contaminated rinsate may be pumped through filter 260 using the pump 250 to remove particles from the contaminated rinsate solution. The refreshed (e.g., filtered) rinsate solution may then be recirculated into the liner 210 for further rinsing of the chamber component part 220. During the cleaning process, waste material from the filter 260 may be removed from the cleaning system 300 via drain line 350 and drain 360. At any point during the cleaning process, samples of the rinsate solution may be removed from the liner 210 via sample outlet 320. The sample of the rinsate solution will flow through the dedicated fluid sampling line 330 through the LPC 240 where a particle count is performed. If the results of the particle count are greater than a previously determined particle count, the endpoint has not been reached and the cleaning process will continue. If the results of the particle count are less than the previously determined particle count, the endpoint has been reached and the cleaning process ends. Sampling by the LPC 240 may be intermittent or continuous.

FIG. 4 is a schematic view of one embodiment of a wet bench set-up 400 according to embodiments described herein. Portions of the side view are illustrated in perspective to assist in the ease of explanation. The wet bench set-up 400 is similar to the wet bench set-up 120; however, the wet bench set-up 400 is configured for delivering both a cleaning solution and a rinsing solution to clean the chamber component part 220. The wet bench set-up 400 comprises a wet bench 402 and the cleaning vessel assembly 130. The wet bench 402 provides support for the cleaning vessel assembly 130. The wet bench 402 may also serve as an overflow basin to catch any cleaning chemicals which overflow the cleaning vessel assembly 130. The wet bench 402 may also function as a fume hood when used in cleaning processes which generate gases and/or particulates. Although shown with the wet bench 402, in certain embodiments, the cleaning vessel assembly 130 is used in a standalone fashion without the wet bench 402. For example, the cleaning vessel assembly 130 may be used without a wet bench in well ventilated areas where there is less concern about the buildup of fumes.

The wet bench 402 may comprise a frame 404 which forms an overflow basin 406 for both holding the cleaning vessel assembly 130 and capturing any fluids which may overflow the cleaning vessel assembly 130 during processing. The overflow basin 406 may include a sink drain line 408 for removing captured fluids from the overflow basin 406.

The cleaning vessel assembly 130 comprises an outer cleaning basin 414 which circumscribes the liner 210 that holds the component part to be cleaned, a transducer 416 positioned within the outer cleaning basin 414, and a support 418 positioned within the outer cleaning basin 414 for supporting the liner 210.

Although shown as cylindrical in FIG. 4, it should be understood that the outer cleaning basin 414 and/or the liner 210 may be any shape, for example, oval, polygonal, square or rectangular. In one embodiment, the outer cleaning basin 414 and/or the liner 210 may be fabricated from a material such as polypropylene (PP), polyethylene (PE)) polyvinyl difluoride (PVDF) or coated metal (e.g., aluminum with an ETFE coating) that will not be attacked by the cleaning chemistry and will not produce a significant amount of particulates.

The transducer 416 is configured to provide either ultrasonic or megasonic energy to a cleaning region within the liner 210 where the chamber component part 220 is positioned. The transducer 416 may be implemented, for example, using piezoelectric actuators, or any other suitable mechanism that can generate vibrations at ultrasonic or megasonic frequencies of desired amplitude. The transducer 416 may be a single transducer, as shown in FIG. 4, or an array of transducers, oriented to direct ultrasonic energy into the cleaning region of the liner 210 where the component part is positioned. When the transducer 416 directs energy into the cleaning fluid in the liner 210, acoustic streaming, i.e. streams of micro bubbles, within the cleaning fluid may be induced. The acoustic streaming aids the removal of contaminants from the component part 220 being processed and keeps the removed particles in motion within the cleaning fluid hence avoiding reattachment of the of the removed particles to the component part surface. The transducer 416 may be configured to direct ultrasonic or megasonic energy in a direction normal to an edge of the component part 220 or at an angle from normal. In one embodiment, the transducer 416 is dimensioned to be approximately equal in length to a mean or outer diameter of the component part 220 to be cleaned. The transducer 416 may be coupled to an RF power supply 422.

While only one transducer 416 is shown positioned below the liner 210, multiple transducers may be used with certain embodiments. For example, additional transducers may be placed in a vertical orientation along the side of the liner 210 to direct ultrasonic or megasonic energy toward the component part 220 from the side. The transducer 416 may be positioned inside the liner 210 or outside of the liner 210 for indirect ultrasonication. The transducer 416 may be positioned outside of the outer cleaning basin 414. In one embodiment, the transducer 416 may be positioned in the overflow basin 406 to direct ultrasonic or megasonic energy toward the component part 220. Although the transducer 416 is shown as cylindrical, it should be understood that transducers of any shape may be used with the embodiments described herein.

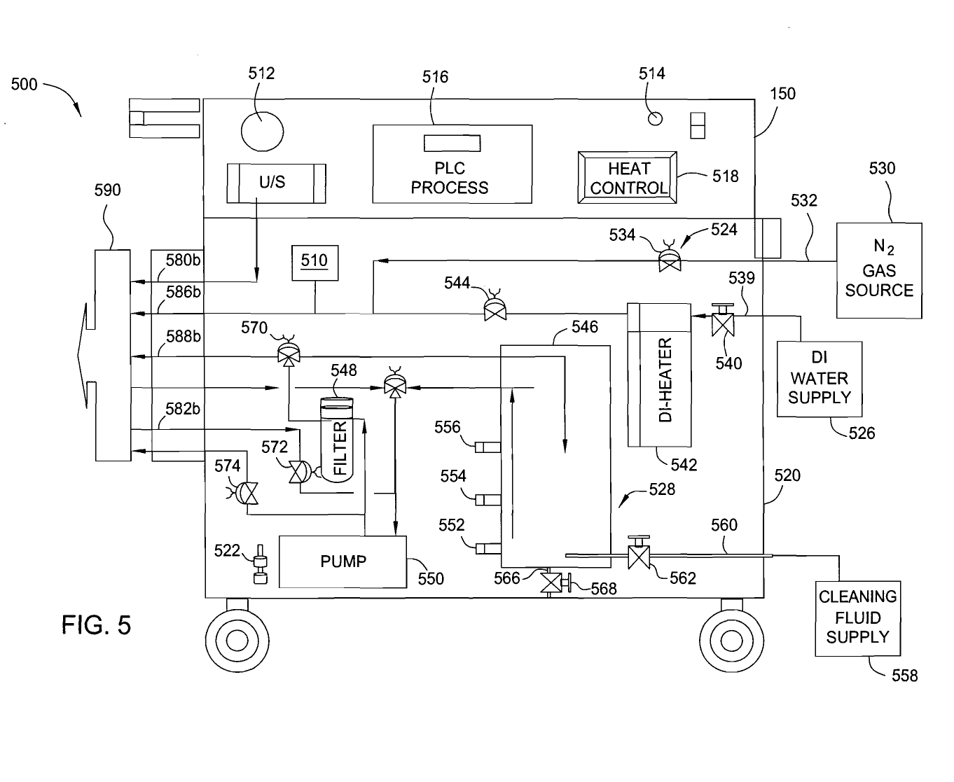

The wet bench set-up 400 also comprises one or more fluid delivery lines 582a, 584, 586a, and 588a for delivering cleaning fluids to the wet bench set-up and returning used cleaning fluids to the portable cleaning cart 500 (see FIG. 5) for recycling and reuse. The fluid delivery lines are configured to mate with corresponding fluid delivery lines 582b, 586b, and 588b on the portable cleaning cart 500 using, for example, connect fittings and disconnect couplings shown as a “Quick Connect” 590.

FIG. 5 is a schematic side view of one embodiment of a portable cleaning cart 500 showing a fluid flow circuit schematic diagram comprising a surface particle endpoint detection system 510 according to embodiments described herein. The surface particle endpoint detection system 510 may be similar to the surface particle endpoint detection systems 110 and 310 disclosed in FIGS. 1-3. The portable cleaning cart 500 may be coupled with the system controller 150 for controlling the cleaning process and a cleaning fluid supply module 520 for supplying and recycling cleaning and rinsate solution. The system controller 150 may be separate from or mounted to the portable cleaning cart 500.

In one embodiment, the system controller 150 comprises controller components selected from at least one of the following: a PhotoMeghelic meter 512, a leak alarm 514 for detecting leaks within the portable cleaning cart, a programmable logic controller 516 for controlling the overall cleaning system, and an in-line heat controller 518. In one embodiment, the leak alarm 514 is electronically coupled with a plenum leak sensor 522 for detecting the presence of fluid in the bottom of the portable cart 500. In one embodiment, the system controller 150 is coupled with the transducer 416 via a communication line 580 and controls the power supplied to the transducer 416.

In one embodiment, the cleaning fluid supply module 520 includes an inert gas module 524 for supplying an inert gas, such as nitrogen (N₂) which may be used as a purge gas during the cleaning process, a DI water supply module 526 for supplying deionized water during the cleaning process, and a cleaning fluid supply module 528 for supplying cleaning fluid and recycling used cleaning fluid.

With regard to the inert gas module 524, as discussed above, the use of nitrogen is exemplary and any suitable carrier gas/purge gas may be used with the present system. In one embodiment, the inert gas is supplied from a nitrogen gas source 530 to a main nitrogen gas supply line 532. In one embodiment, the nitrogen gas source comprises a facility nitrogen supply. In one embodiment, the nitrogen source may be a portable source coupled with the portable cleaning cart 500. In one embodiment, the nitrogen gas supply line 532 comprises a manual shutoff valve (not shown) and a filter (not shown) for filtering contaminants from the nitrogen gas. A two-way valve 534 which may be an air operated valve is also coupled with the nitrogen gas supply line 532. When the two-way valve is open, nitrogen gas flows through the supply line 532 and into the outer cleaning basin 414. Nitrogen may be used in several different applications within the cleaning system. The nitrogen gas supply line 532 may also contain additional valves, pressure regulators, pressure transducers, and pressure indicators which are not described in detail for the sake of brevity. In one embodiment, nitrogen gas may be supplied to the outer cleaning basin 414 via fluid supply line 584.

With regard to the DI water supply module 526, the use of DI water is exemplary and any cleaning fluid suitable for cleaning may be used with the present cleaning system 100. In one embodiment, the DI water is supplied from a DI water supply module 526 to a main DI water supply line 539. In one embodiment, the DI water source comprises a facility DI supply. In one embodiment, the DI water source may be a portable source coupled with the portable cleaning cart 500. In one embodiment, the DI water supply line 539 comprises a shutoff valve 540 and a heater 542 for heating the DI water to a desired temperature for assisting in the cleaning process. The heater 542 may be in electronic communication with the heat controller 518 for controlling the temperature. The DI water supply line 539 further comprises a two-way valve 544 which may be an air operated valve which is used for controlling the flow of DI water into the outer cleaning basin 414. When the two-way valve 544 is open, DI water flows into the outer cleaning basin 414. When the two-way valve 544 is closed and two-way valve 534 is open, nitrogen purge gas flows into the outer cleaning basin 414. The DI water supply line 539 may also contain additional valves, pressure regulators, pressure transducers, and pressure indicators which are not described in detail for the sake of brevity. In one embodiment, DI water may flow into the outer cleaning basin 414 via supply line 586. The surface particle endpoint detection system 510 may be fluidly coupled with the DI water supply line 539. In certain embodiments, the surface particle endpoint detection system 510 is separate from the DI water supply line 586a.

The cleaning fluid supply module 528 comprises a cleaning fluid supply tank 546 for storing cleaning fluid, a filter system 548 for filtering used cleaning fluid, and a pump system 550 for pumping cleaning fluid into and out of the cleaning fluid supply module 528. The cleaning fluid may include rinsate solution (e.g., deionized water (DIW)), one or more solvents, a cleaning solution such as standard clean 1 (SC1), selective deposition removal reagent (SDR), surfactants, acids, bases, or any other chemical useful for removing contaminants and/or particulates from a component part.

In one embodiment, the cleaning fluid supply tank 546 is coupled with a cleaning fluid supply 558 via a supply line 560. In one embodiment, the cleaning fluid supply line 560 comprises a shut-off valve 562 for controlling the flow of cleaning fluid into the cleaning fluid supply tank 546. The cleaning fluid supply line 560 may also contain additional valves, pressure regulators, pressure transducers, and pressure indicators which are not described in detail for the sake of brevity. In one embodiment, the cleaning fluid supply tank 546 is coupled with the outer cleaning basin 414 via supply line 588.

In one embodiment, the cleaning fluid supply tank 546 is coupled with a cleaning fluid supply drain 566 for removing cleaning fluid from the cleaning fluid supply tank 546. The flow of cleaning fluid through the cleaning fluid supply drain 566 is controlled by a shut-off valve 568.

The cleaning fluid supply tank 546 may also include a plurality of fluid level sensors for detecting the level of processing fluid within the cleaning fluid supply tank 546. In one embodiment, the plurality of fluid sensors may include a first fluid sensor 552 which indicates when the fluid supply is low and that the pump system 550 should be turned off. When the level of cleaning fluid is low, the first fluid level sensor 552 may be used in a feedback loop to signal the cleaning fluid supply 558 to deliver more cleaning fluid to the cleaning fluid supply tank 546. A second fluid level sensor 554 which indicates that the cleaning fluid supply tank 546 is full and the pump 550 should be turned on. A third fluid sensor 556 which indicates that the cleaning fluid supply tank 546 has been overfilled and that the pump 550 should be turned off. Although one fluid level sensor 434 is shown in the embodiment of FIG. 2, any number of fluid level sensors 434 may be included on the outer cleaning basin 414.

Used cleaning fluid may be returned from the outer cleaning basin 414 to the filter system 548 where particulates and other contaminants may be removed from the used cleaning fluid to produce renewed (e.g., filtered) cleaning fluid. In one embodiment, used cleaning fluid may be returned from the overflow basin via fluid recycling line 582. The recycling line 582 may also contain additional valves, pressure regulators, pressure transducers, and pressure indicators which are not described in detail for the sake of brevity. After filtration, the renewed cleaning fluid may be recirculated back to the cleaning fluid supply tank 546 via a three-way valve 570. In one embodiment, the three-way valve 570 may also be used in conjunction with the pump system 550 to recirculate fluid through the cleaning system to flush the cleaning system 100. In one embodiment, a two-way valve 572 which may be an air operated valve may be used to pull DI water through the input of the pump system 550. In one embodiment, a two-way valve 574 may be used to pump out DI water to drain.

In one embodiment, a component part 220 is placed on the support 418 positioned within a cleaning liner (not shown), similar to liner 210. A cleaning cycle is commenced by flowing cleaning solution into the cleaning liner. While the cleaning solution is in the cleaning liner, the transducer 416 is cycled on/off to agitate the cleaning solution. The cleaning solution may be purged from the cleaning liner by flowing DI water into the tank. Nitrogen gas may also be used during the purge process. The cleaning/purge cycle may be repeated until the component part 220 has achieved a desired cleanliness. The cleaning liner may then be replaced by the rinsing liner 210 and the component part 220 is placed in the rinsing liner 210. Rinsate solution (e.g., DI water) may be supplied from the DI water supply module 526 to the fluid supply line 586a where the rinsate solution flows into the rinsing liner 210. The transducer 416 may be cycled on/off to agitate the rinsate solution and provide improved rinsing of the chamber component part 220. The contaminated rinsate solution exits the liner 210 where it may be pumped through a filter where particles are removed from the contaminated rinsate solution. The refreshed rinsate solution may then be recirculated into the rinsing liner 210 for further rinsing of the chamber component part 220. At any point during the cleaning process, samples of the rinsate fluid may be removed from the liner 210 and flown through a fluid sampling line through the LPC 240 where a particle count is performed. In certain embodiment, if the results of the particle count are greater than a previously determined particle count, the endpoint has not been reached and the rinsing process will continue. In certain embodiment, if the results of the particle count are greater than a previously determined particle count, the endpoint has not been reached and the chamber component part 220 is exposed to additional cleaning solution. If the results of the particle count are less than the previously determined particle count, the endpoint has been reached and the rinsing process ends.

While the foregoing is directed to embodiments of the invention, other and further embodiments of the invention may be devised without departing from the basic scope thereof.

1. A system for cleaning parts disposed in a liner with a cleaning fluid, comprising:
a portable cart;
a liquid particle counter (LPC) carried by the portable cart, the LPC configured for detachable coupling to a fluid outlet port formed through the liner, the LPC operable to sample rinsate solution exiting the liner; and
a pump carried by the portable cart and configured for fluid coupling to the liner in a detachable manner, the pump operable to recirculate rinsate solution through the liner.

2. The system of claim 1, further comprising:
a circulating fluid supply line carried by the portable cart and coupled to the pump, the circulating fluid supply line configured for detachable coupling with the liner; and
a filter carried by the portable cart and coupled with the circulate fluid supply line, the filter operable to remove particles from the rinsate solution passing through the circulating fluid supply line.

3. The system of claim 2, wherein the LPC is coupled to the circulating fluid supply line.

4. The system of claim 3, further comprising:
a dedicated fluid sampling line for removing a sample of rinsate solution from the liner having a first end coupled with the liner and a second end coupled with the circulating fluid supply line, wherein the LPC is fluidly coupled with the dedicated fluid sampling line.

5. The system of claim 4, further comprising:
a dedicated fluid sampling pump for pumping rinsate through the dedicated fluid sampling line.

6. The system of claim 5, further comprising:
a drain line carried by the portable cart fluidly coupling the filter with a drain for removing waste material from the filter.

7. The system of claim 1, further comprising:
a cleaning vessel having the liner disposed therein; and
a transducer positioned to agitate fluid within the liner.

8. The system of claim 7, wherein the liner comprises a material selected from the group of polypropylene (PP), polyethylene (PE), polyvinyl difluoride (PVDF), and combinations thereof.

9. A system for cleaning parts disposed in a liner with a cleaning fluid, comprising:
a portable cart;
a liner for holding parts to be cleaned during a cleaning process; and
a liquid particle counter (LPC) carried by the portable cart, the LPC configured for detachable coupling to a fluid outlet port formed through the liner, the LPC operable to sample cleaning fluid exiting the liner.

10. The system of claim 9, further comprising:
a cleaning vessel assembly having the liner disposed therein; and
a transducer positioned below the liner to agitate the cleaning fluid within.

11. The system of claim 10, further comprising:
a wet bench set-up comprising:
a frame which forms an overflow basin for holding the cleaning vessel assembly and capturing any fluids which may overflow from the cleaning vessel assembly during the cleaning process; and
a sink drain line for removing any fluids captured by the overflow basin during the cleaning process.

12. The system of claim 11, wherein the portable cleaning cart comprises:
a system controller for controlling the cleaning process; and
a cleaning fluid supply module for supplying and recycling cleaning fluid to the cleaning vessel assembly.

13. The system of claim 12, wherein the cleaning fluid supply module comprises:
an inert gas module for supplying an inert gas which may be used as a purge gas during the cleaning process;
a deionized (DI) water supply module for supplying deionized water during the cleaning process; and
a first cleaning fluid supply tank for supplying cleaning fluid during the cleaning process.

14. The system of claim 9, further comprising:
a pump carried by the portable cart and configured for fluid coupling to the liner in a detachable manner, the pump operable to recirculate cleaning fluids through the liner;
a circulating fluid supply line carried by the portable cart and coupled to the pump, the circulating fluid supply line configured for detachable coupling with the liner; and
a filter carried by the portable cart and coupled with the circulating fluid supply line, the filter operable to remove particles from the cleaning fluid passing through the circulating fluid supply line.

15. The system of claim 14, wherein the LPC is fluidly coupled to the circulating fluid supply line.

16. The system of claim 15, further comprising:
a dedicated fluid sampling line for removing a sample of cleaning fluid from the liner having a first end coupled with the liner and a second end coupled with the circulating fluid supply line, wherein the LPC is fluidly coupled with the dedicated fluid sampling line.

17. The system of claim 16, further comprising:
a dedicated fluid sampling pump for pumping rinsate through the dedicated fluid sampling line.

18. The system of claim 17, further comprising:
a drain line carried by the portable cart fluidly coupling the filter with a drain for removing waste material from the filter.
